(19) United States
(12) Patent Application Publication
(10) Pub. No.: US 2023/0066455 A1
(43) Pub. Date: Mar. 2, 2023

(54) GLASS ARTICLE WITH TRANSPARENT, LIGHT CONVERTING SPATIAL LOCATION ENCODING LAYER

(71) Applicant: CORNING INCORPORATED, Corning, NY (US)

(72) Inventor: Timothy James Orsley, San Jose, CA (US)

(21) Appl. No.: 17/981,694

(22) Filed: Nov. 7, 2022

Related U.S. Application Data
(62) Division of application No. 16/639,887, filed on Feb. 18, 2020.
(60) Provisional application No. 62/548,545, filed on Aug. 22, 2017.

(51) Int. Cl. C03C 17/34; C03C 3/04; C03C 17/40; H01L 25/075; H01L 27/30; H01L 33/50

(52) U.S. Cl. CPC C03C 17/3435; C03C 3/04; C03C 17/40; H01L 25/0753; H01L 27/30; H01L 33/50; C03C 2201/10; C03C 2217/281; C03C 2217/93

(57) ABSTRACT

A glass article including a spatial location encoding layer for use in a digital inking system, an associated electronic device, a method of making and a digital inking system are provided. The glass article utilizes a plurality of light converting regions disposed on the surface of the glass in a pattern encoding spatial location. The plurality of light converting regions are formed from an inorganic, environmentally stable material, such as alternating stacks of III-V compound materials.

### CROSS-REFERENCE TO RELATED APPLICATIONS

This application is a divisional of U.S. patent application Ser. No. 16/639,887 filed on Feb. 18, 2020, which claims the benefit of priority under 35 U.S.C. § 371 of International Application No. PCT/US18/47063, filed on Aug. 20, 2018, which claims the benefit of U.S. Provisional Application Ser. No. 62/548,545 filed on Aug. 22, 2017, the contents of which are relied upon and incorporated herein by reference in their entirety as if fully set forth below.

### BACKGROUND

The disclosure relates generally to the field of glass articles, and specifically to glass articles with a transparent layer encoding spatial location information, such as for a digital inking system. Generally, conventional digital inking systems utilize electro-magnetic resonance or electrostatic capacitance to track position of a stylus across a screen of an electronic device. The tracked position of the stylus is converted to a digital representation of the writing, drawing or other image that is being formed via movement of the stylus.

### SUMMARY

One embodiment of the disclosure relates to a glass article including a glass layer. The glass layer includes a first major surface and a second major surface opposite the first major surface. The glass article includes a plurality of light converting regions disposed on the first major surface of the glass layer. Each of the plurality of light converting regions includes a layer of a first III-V compound and a layer of a second III-V compound. The first III-V compound is different from the second III-V compound. The plurality of light converting regions are arranged in a pattern relative to the first major surface which encodes information indicating a spatial location of each light converting region along the first major surface of the glass layer.

An additional embodiment of the disclosure relates to an electronic display device configured for digital handwriting conversion. The electronic display device includes a housing and a cover glass layer supported by the housing. The cover glass layer includes an outward facing major surface and an inward facing major surface. The electronic display device includes a plurality of light converting regions located below the cover glass layer, and the plurality of light converting regions are arranged in a pattern relative to the outward facing major surface which encodes information indicating a spatial location of each light converting region relative to the outward facing major surface of the cover glass layer. The plurality of light converting regions are formed from an inorganic material that absorbs light having a wavelength less than 400 nm and that emits light having a peak wavelength greater than 650 nm in response to the absorbed light. A region of the electronic display device within the housing surrounding the plurality of light converting regions is not hermetically sealed such that the housing includes at least one pathway for oxygen to traverse into the housing to reach the plurality of light converting regions.

An additional embodiment of the disclosure relates to a method of forming an article for a digital inking system. The method includes depositing a layer of light converting inorganic material onto a major surface of a sheet of transparent material in a pattern which encodes information indicating a spatial location of each region of the pattern along the major surface of the sheet of transparent material. The major surface of the sheet of transparent material and the layer of light converting inorganic material are exposed to oxygen during or following the depositing step. The light converting inorganic material is oxygen insensitive such that exposure to oxygen does not degrade the light converting inorganic material.

Additional features and advantages will be set forth in the detailed description that follows, and, in part, will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

The accompanying drawings are included to provide a further understanding and are incorporated in and constitute a part of this specification. The drawings illustrate one or more embodiment(s), and together with the description serve to explain principles and the operation of the various embodiments.

### BRIEF DESCRIPTION OF THE DRAWINGS

FIG. 1 is a schematic view of an electronic device having a spatial location encoding layer for use in a digital inking system, according to an exemplary embodiment.

FIG. 2 is a cross-sectional view of a glass article having a spatial location encoding layer for use in a digital inking system, according to an exemplary embodiment.

FIG. 3 is a plan view of a glass article having a spatial location encoding layer for use in a digital inking system, according to an exemplary embodiment.

FIG. 4 is a cross-sectional view of a glass article having a spatial location encoding layer for use in a digital inking system, according to another exemplary embodiment.

FIG. 5 is a schematic view of an electronic device having a spatial location encoding layer for use in a digital inking system, according to another exemplary embodiment.

FIG. 6 is a schematic view of an electronic device having a spatial location encoding layer for use in a digital inking system, according to another exemplary embodiment.

FIG. 7 is a schematic view of a glass article having a spatial location encoding layer for use in a digital inking system located on top of a display stack, according to an exemplary embodiment.

FIG. 8 is a schematic view illustrating scalability of the spatial location encoding pattern to different sized devices, according to an exemplary embodiment.

FIG. 9 is a schematic view of a digital inking system utilizing the electronic device and spatial location encoding layer of FIGS. 1-3, according to an exemplary embodiment.

### DETAILED DESCRIPTION

Referring generally to the figures, various embodiments of a glass article with a spatial location encoding layer are shown and described. The glass articles discussed herein may be utilized as part of a digital inking system in which a position of a stylus relative to a glass article and to the spatial location encoding layer are tracked to generate a digital representation of the stylus movements (e.g., a digital representation of writing, drawing, etc.). The glass article may be the cover glass of an electronic device, a glass layer bonded to a cover glass layer, a glass layer on top of the display stack, etc.

The spatial location encoding layer discussed herein is formed from a material that provides a unique combination of properties providing a combination of functionality not previously achieved in digital inking systems. In various embodiments, the spatial location encoding layer is formed from layers of different III-V compounds deposited on the glass material in a pattern that encodes spatial location. The spatial location encoding layer is formed from a material that absorbs UV light (and not light from the underlying display) and emits dark red, NIR, and/or IR light which results in a spatial location encoding layer that is transparent to visible spectrum. This allows the spatial location encoding layer discussed herein to be used in conjunction with display devices without degrading quality of the display, either through absorption of visible spectrum light or by emitting light in a pattern noticeable to user.

Further, in various embodiments, the material utilized for the spatial location encoding layer discussed herein is robust and environmentally stable. In particular, the materials discussed herein are generally not sensitive to oxygen, moisture and/or sunlight. This environment stability is believed to improve device performance by eliminating the need for hermetic sealing of the portion of the device housing the spatial location encoding layer. Further, the environmental stability also improves/simplifies manufacturability by allowing for exposure of the spatial location encoding layer to atmosphere, oxygen, and/or moisture during or following deposition of the spatial location encoding layer.

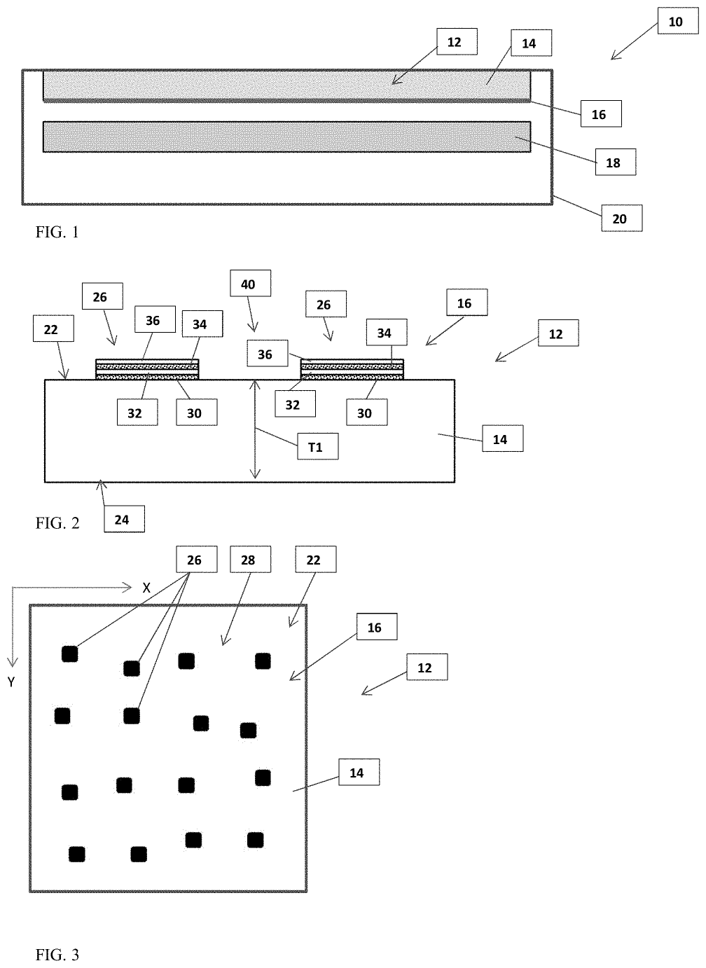

Referring to FIG. 1, an electronic device 10 is shown according to an exemplary embodiment. Electronic device 10 includes a glass article 12. Glass article 12 has a glass layer, shown as glass layer 14, and a spatial location encoding layer 16. In the embodiment shown in FIG. 1, glass article 12 is positioned above a display stack 18, such as an LED or OLED display device, and spatial location encoding layer 16 is located below glass layer 14 and also is above display stack 18. In the specific embodiment shown, glass article 12 is the cover glass layer of electronic device 10. Electronic device 10 includes a housing 20 that supports and houses glass article 12, display stack 18 along with the various electronics, processors, power systems/batteries, communications systems, etc. of the associated electronic device.

Referring to FIG. 2 and FIG. 3, details of glass article 12 and spatial location encoding layer 16 are shown. Glass article 12 is a sheet of relatively thin glass material having a first major surface, shown as inward facing surface 22, and a second major surface, shown as outward facing surface 24, opposite inward facing surface 22. In this embodiment, spatial location encoding layer 16 includes a plurality of light converting regions 26 disposed on inward facing surface 22. In this particular arrangement, light converting regions 26 are coupled to inward facing surface 22 such that an innermost layer of each regions 26 is in direct contact with inward facing surface 22 and face toward display stack 18 when supported by housing 20 (shown in FIG. 1). In specific embodiments, each of the light converting regions 26 are directly deposited (e.g., the innermost layer of each region 26 is directly deposited) onto inward facing surface 22 forming the arrangement shown in FIG. 2.

In general, as shown in an exemplary embodiment in FIG. 3, light converting regions 26 are arranged in a pattern 28 relative to inward facing surface 22 and also relative to outward facing surface 24 which encodes information indicating a spatial location of each region along inward facing surface 22. Specifically, each region 26 is arranged, positioned, shaped or otherwise configured to indicate its location along inward facing surface 22 of glass article 12. In a specific embodiment, the pattern of the dots within a small group or subset is unique and can be decoded to determine absolute position by observing a small subset of contiguous dots. As will be explained in more detail below regarding FIG. 9, this position encoding allows for a digital inking system to track a position of stylus to produce a digital representation of the stylus movement.

As noted above, in contrast to other digital inking systems, the light converting regions of spatial location encoding layer 16 are formed from a material that is invisible to the user, transparent to visible light and also environmentally stable. In the embodiment shown in FIG. 2, light converting regions 26 are each formed from a stack of alternating layers of different III-V compounds. As used herein, a III-V compound is a chemical compound with at least one group III (IUPAC group 13) element and at least one group V element (IUPAC group 15). In such arrangements, each light converting region 26 includes at least one layer of a first III-V compound and at least one layer of a second III-V compound, which is different from the first III-V compound. In specific embodiments, each light converting region 26 includes at least two layers of the first III-V compound and at least two layers of the second III-V compound, layered in an alternating stacked arrangement as shown in FIG. 2.

While there are a wide variety of potential III-V compounds and stack arrangements that can be utilized, in specific embodiments, each light converting region 26 includes a first layer 30 of a first III-V compound and a first layer 32 of a second III-V compound located on the first layer 30. In such embodiments, each light converting region 26 includes a second layer 34 of the first III-V compound and a second layer 36 of the second III-V compound. In a specific embodiment, the first III-V compound is aluminum nitride (AlN), and the second III-V compound is gallium nitride (GaN).

In these specific embodiments, lattice parameter mismatches between the GaN layers and the AlN layers create a local strain at the interface between AlN layer and GaN layer, resulting in GaN/AlN quantum nano-structures. Such quantum nano-structures trap free current carriers (i.e., electrons and holes in a semiconductor), hence improving their radiative recombination rates. In particular, the quantum nano-structures absorb UV light and reemit light in the red, NIR or IR spectrum.

The stack of alternating III-V compounds discussed herein provide a number of advantages for use in a digital inking system. As one example, the stacked arrangement of AlN and GaN is particularly suitable for use with an electronic display device because it both absorbs and emits light outside of or near the ends of the visible spectrum. In particular, the stacked arrangement of AlN and GaN absorbs light having a wavelength less than or equal to 400 nm and emits light having both a peak wavelength greater than 650 nm and a substantial portion of emitted light in the NIR or IR wavelength ranges. Because the absorbed light is in the ultraviolet range, absorption of light by regions 26 does not result in regions being visible to the naked eye by distorting the light emitted from the underlying display, and because the majority of the emitted light is in the dark red or infrared range, emission of light by regions 26 does not distort the display provided by display 18.

The absorption and emission spectra of regions 26 are also used to track stylus movement without impacting image quality displayed by device 10. As will be discussed in more detail below regarding FIG. 9, the stylus of the digital inking system transmits UV light to stimulate regions 26 as the stylus moves over the display of an electronic device. The stylus then receives the emitted dark red, NIR or IR signal from the stimulated regions 26 allowing the position and movement of the stylus over the display to be detected and translated into a digital image of the stylus movement.

In addition to the desirable absorption and emission spectra of regions 26, the III-V compound materials of spatial location encoding layer 16 are environmentally stable. It is Applicant's understanding that quantum dots are particularly susceptible to degradation in the presence of oxygen and moisture. As such, in embodiments wherein the spatial location encoding layer 16 utilizes quantum dots as the light converting regions 26, hermetic sealing of the device housing 20 may be required. Manufacturing in oxygen and/or moisture free environments may also be needed for the production of quantum-dot based devices. However, formation of spatial location encoding layer 16 utilizing the III-V compound materials, as discussed above, allows housing 20 to be a non-hermetically sealed housing that includes at least one pathway that allows oxygen and/or moisture (e.g., from the atmosphere) to traverse the housing 20 to reach layer 16. In various embodiments, the glass article and position encoding layer materials discussed herein eliminates the need for such hermetic sealing and environmental control during manufacture.

In addition to being oxygen/moisture stable, the III-V compound materials of spatial location encoding layer 16 also are resistant to degradation in sunlight. In contrast, Applicant believes that UV absorbing inks and dyes typically have a relatively short half-life under sunlight exposure under normal operating conditions.

In various embodiments, the present disclosure provides for III-V compound-based spatial location patterning in combination with a variety of glass materials that provide suitable support for spatial location encoding layer 16 in a variety of applications. In one or more embodiments, glass layer 14 is a strengthened glass material. In such embodiments, glass layer 14 is strengthened to include compressive stress that extends from one or more surface (e.g., surfaces 22 and 24) to a depth of compression (DOC). The compressive stress regions are balanced by a central portion exhibiting a tensile stress. At the DOC, the stress crosses from a positive (compressive) stress to a negative (tensile) stress.

In some embodiments, glass layer 14 may be strengthened mechanically by utilizing a mismatch of the coefficient of thermal expansion between portions of the article to create a compressive stress region and a central region exhibiting a tensile stress. In some embodiments, glass layer 14 may be strengthened thermally by heating the glass to a temperature above the glass transition point and then rapidly quenching.

In some embodiments, glass layer 14 is formed from a chemically strengthened glass material. In such embodiments, glass layer 14 may be chemically strengthened by ion exchange. In the ion exchange process, ions at or near the surface of glass layer 14 are replaced by or exchanged with larger ions having the same valence or oxidation state. In those embodiments in which glass layer 14 comprises an alkali aluminosilicate glass, ions in the surface layer of the article are replaced by larger ions, such as monovalent alkali metal cations, such as Li⁺, Na⁺, K⁺, Rb⁺, and Cs⁺. Alternatively, monovalent cations in the surface layer may be replaced with monovalent cations other than alkali metal cations, such as Ag⁺ or the like. In such embodiments, the monovalent ions (or cations) exchanged into glass layer 14 generate a stress.

In specific embodiments, glass layer is formed from an alkali aluminosilicate glass composition, or an alkali aluminoborosilicate glass composition that is chemically strengthened via ion exchange. In some such embodiments, the chemically strengthened compression layer has a depth of compression (DOC) in a range from about 30 μm to about 90 μm and a compressive stress on inward facing surface 22 and/or outward facing surface 24 of between 300 MPa to 1000 MPa. In other embodiments, glass layer 14 is a soda lime glass material or any other glass material as may be needed for a particular electronic display device application.

In some such embodiments, device 10 is a mobile electronic device, and glass layer 14 is a chemically strengthened cover glass layer of the mobile electronic device. As shown in FIG. 2, glass layer 14 has an average thickness, T1, measured between opposing major surfaces 22 and 24. In cover glass applications, T1 of glass layer 14 is generally 0.3 mm to 2 mm.

As shown in the embodiments of FIG. 2 and FIG. 3, light converting regions 26 may be formed by individual stacks of III-V compound materials spaced and separated from each other by gaps 40 to form pattern 28. In another embodiment, spatial location encoding layer 16 may be formed from continuous, contiguous and alternating III-V material layers 30, 32, 34, and 36 that cover a substantial portion of inward facing surface 22 of glass 14.

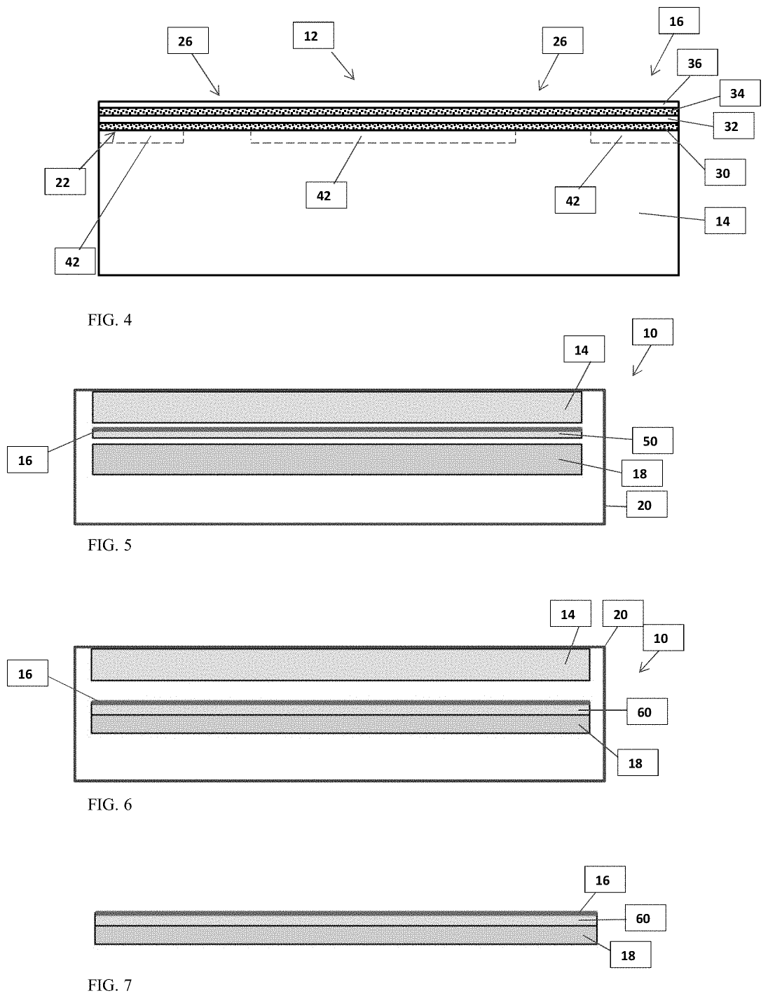

In this embodiment, as shown in FIG. 4, a masking material 42 may be provided to deactivate photoluminescence of portions of layer 16, to block portions of layer 16 from receiving UV light, and/or to prevent portions of layer 16 from emitting IR light. In these embodiments, the pattern 28 of light converting regions 26 are formed from the unmasked portions of layer 16. In various embodiments, masking material 42 is positioned such that unmasked portions of layer 16 form regions 26 and the spatial location encoding pattern 28 as discussed above. In a specific embodiment, masking material 42 may be ions, such as oxygen ions, that are implanted into the masked areas of layer 16, which deactivates the ability of these areas to photoluminescence. In other embodiments, masking material 42 may be embedded in glass layer 14, located on surface 22, located on surface 24 or any other suitable location for masking portions of layer 16.

Referring to FIGS. 5-7, spatial location encoding layer 16 may be located at a variety of positions relative to a display stack 18. As shown in FIG. 5, electronic display device 10 may include a support glass layer 50, and spatial location encoding layer 16 is located on support glass layer 50. Support glass layer 50 is a piece of glass material separate from cover glass layer 14. In this arrangement, spatial location encoding layer 16 is located directly on one of the major surfaces of support glass layer 50 in the manner discussed above regarding regions 26 located on glass layer 14.

In specific embodiments, cover glass layer 14 is formed from a first glass composition and support glass layer 50 is formed from a second glass composition different than the first glass composition. In some embodiments, cover glass layer 14 may be formed from a glass material that is not suitable for deposition of layer 16. For example, in some embodiments where cover glass layer 14 is a chemically strengthened glass layer, temperatures during deposition of the III-V materials of layer 16 may allow for ion migration within layer 14, thereby reducing the surface compression providing strength to cover glass layer 14. In such embodiments, support glass layer 50 may be a relatively thin piece of unstrengthened glass material to which layer 16 is bonded rather having layer 16 directly deposited on to cover glass layer 14. In such embodiments, following deposition of layer 16, support glass layer 50 may then be associated with cover glass layer 14 to provide position encoding of layer 16 without requiring the strengthened cover glass layer itself to be exposed to the high temperatures during deposition of layer 16. In some such embodiments, support glass layer 50 may be formed from a glass material having a glass transition temperature greater than 520 degrees C.

In general, support glass layer 50 is positioned within housing 20 such that layer 16 provides spatial location encoding relative to cover glass 14 as discussed above. In one embodiment, as shown in FIG. 5, support glass layer 50 bearing position encoding layer 16 is bonded to cover glass layer 14 for example via an optically clear adhesive material. In another embodiment as shown in FIG. 6, spatial encoding layer 16 may be formed on a display glass layer 60 which may be positioned on top of display stack 18 in a position that allows layer 16 to provide spatial location encoding relative to cover glass 14 as discussed above. As shown in FIG. 7, in some embodiments, display glass layer 60 may be provided with display stack 18 without cover glass layer 14. In some such embodiments, display glass layer 60 is a glass layer that is already part of display stack 18. For example, if display stack 18 is part of an OLED display, display glass layer 60 may be the encapsulation glass layer located on top of the display glass.

Support glass layer 50 and display glass layer 60 may have a wide range of thicknesses depending on the size of device 10 and its position within device 10. In various embodiments, support glass 50 and/or display glass layer 60 have an average thickness between its first and second major surfaces of 0.1 mm to 3.2 mm. In specific embodiments, support glass 50 and/or display glass layer 60 may be a borosilicate glass (e.g., Willow Glass available from Corning, Inc.) having a thickness between 0.1 mm and 1 mm. In other embodiments, support glass 50 and/or display glass layer 60 may have a large area (e.g., for use in large TV sized displays) and may be formed from soda lime glass having a thickness between 1 mm and 3.2 mm.

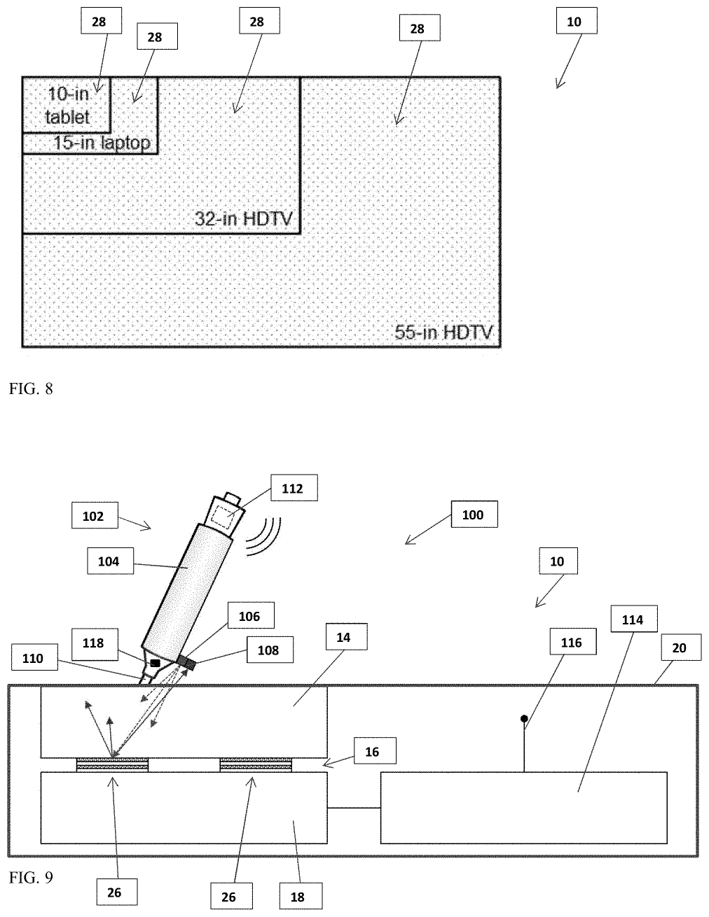

As shown in FIG. 8, the glass articles with spatial location encoding layer 16 as discussed above (e.g., glass layer 14. support glass 50 or display glass layer 60) may find use in a wide variety of electronic display devices. In particular embodiments, the pattern of spatial location encoding layer 16 is extensible to extremely large areas. As such, glass layer 14, support glass 50 and/or display glass layer 60 may be used to provide digital inking functionality to devices as small as smart phones and tablets, to laptop displays and large HD television displays. In some embodiments, small sized displays could have a common spatial encoding pattern as a sub-area of a larger display. That is, a large global pattern sufficient to uniquely encode position across a large display could be truncated appropriately for smaller displays. For example, as shown in FIG. 8, the spatial encoding pattern of the upper left area of a larger display may form the complete pattern of across the entire area of a smaller display.

In various embodiments, the disclosure herein relates to a method of forming a glass article having a position encoding layer 16 (e.g., glass article 12, support glass layer 50, etc.). In such embodiments, one or more layer of a light converting inorganic material is deposited onto a major surface of a sheet of transparent material (e.g., glass 14, support glass 50, a plastic material, other suitable transparent material, etc.) in a pattern which encodes the spatial location of each region of the pattern along the major surface of the sheet of transparent material. In specific embodiments, the deposited light converting inorganic material includes the III-V compounds deposited to form regions 26 as discussed above. In various embodiments, the major surface of the sheet of transparent material and the layer of light converting inorganic material are exposed to oxygen during or following the step of depositing the inorganic light converting material. In some such embodiments, the light converting inorganic material is oxygen insensitive such that exposure to oxygen does not degrade the light converting inorganic material. In specific embodiments, details of the light converting inorganic material and deposition processes are found in published PCT application, WO 2017/089857, published Jun. 1, 2017, which is incorporated herein by reference in its entirety.

FIG. 9 shows a digital handwriting conversion system, such as digital inking system 100 utilizing one of the embodiments of electronic display device 10, as discussed above. As shown, digital inking system 100 includes a digital writing device, shown as stylus 102. Stylus 102 includes a body 104 that supports a UV light source 106, an optical sensor 108, a writing tip 110 and a communication system 112.

In use, a user grips body 104 and moves stylus 102 across cover glass layer 14 in a motion to form writing, drawings, etc. As tip 110 engages glass layer 14, a switch (e.g., a switch in the tip) is triggered causing activation of UV light source 106 (e.g., a UV LED) which directs UV light through cover glass 14. The UV light from light source 106 is absorbed by specific light converting regions 26 as stylus is moved over them, and in turn, the light converting regions 26 that absorbed UV light emit light (e.g., dark red, NIR, IR, light have a peak wavelength at 650 nm, etc.), which is detected by optical sensor 108. Communications system 112 of stylus 102 communicates information indicative of the position of the light converting regions 26 that where stimulated via the UV light to a processing system 114. In some embodiments, the pattern of the observed dots is decoded to determine absolute position, then that position can be communicated. As shown in FIG. 9, electronic display device 10 includes a communications system 116 that receives the information from stylus 102, and in specific embodiments, these communication systems are wireless (e.g., Bluetooth communication).

Because the pattern of light converting regions 26 encode their absolute spatial location relative to cover glass 14 (as discussed above) and because light converting regions 26 are stimulated in response to the movement of stylus 102 over cover glass 14, the positional information communicated to processing system 114 from stylus 102 represents the movement of stylus relative to cover glass 14. From this information, processing system 114 is configured to cause the display of a digital image via a display of electronic device 10 that is representative of the tracked movement of stylus 102. In contrast to touchscreen-based digital inking systems, digital inking system 100 is not sensitive to contact between glass 14 and a user's hand, and thus allows the user to adopt a natural writing position with the hand resting on or touching the glass.

In various embodiments, the position information from stylus 102 can also be provided to a remote display to display the digital image representing stylus movement. For example, if a professor were giving a lecture to a live classroom using a PowerPoint deck upon which he was adding annotations, those annotations could be observed on an in-class display device, as well as remotely by those listening in (or even later in time as the digital ink could be synchronized with audio or video of a recording of the lecture).

Stylus 102 may be powered by a variety of suitable power supplies. In a specific embodiment, stylus 102 is powered by a rechargeable battery, such as lithium ion battery.

In various embodiments, stylus 102 is configured in a variety of ways to safely operate its UV light source. For example, the switch 118 located in tip 110 of the stylus 102 ensures that the UV light source 106 emits only when tip 110 is depressed. Further, when tip 110 is depressed, optical sensor 108 can start imaging, allowing system 100 to begin detection of activated regions 26 and determination of stylus position, as discussed above. As another safety feature, if such dots are not quickly identified (indicating that stylus 102 is not being directed toward glass layer 14 and layer 16), system 100 is configured to turn off UV light source 106 until tip 110 of stylus 102 is released and then is depressed again following release. This avoids the possibility of manually depressing the stylus tip when UV light source 106 can impinge upon one's eyes.

In some embodiments, system 100 may also include an erasing tool similar to stylus 102. In such embodiments, the erasing tool also has a UV light source and optical sensor, which causes erasing of previously drawn images by moving the eraser over glass 14. In some embodiments, stylus 102 may have an eraser mode allowing it to operate as both the writing stylus and eraser.

In some embodiments, the emission spectrum of the material of layer 16 may overlap with the visible light from the display of electronic device 10. In such embodiments, optical sensor 108 is equipped with a filter to suppress display output, while allowing only IR portions of the emission spectra from regions 26 to reach sensor 108.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more component or element, and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

What is claimed is:

1. A digital inking system comprising an optical sensor and an electronic display device, the electronic display device comprising:
a housing;
an outward facing major surface supported by the housing; and
a plurality of light converting regions arranged in a pattern relative to the outward facing major surface which encodes information indicating a spatial location of each light converting region relative to the outward facing major surface, and
wherein the optical sensor is configured to detect light emitted by the plurality of light converting regions.

2. The digital inking system of claim 1, wherein the plurality of light converting regions are formed from an inorganic material that absorbs UV light and that emits light in response to the absorbed UV light, wherein a substantial portion of the emitted light is in the near IR or IR wavelength ranges.

3. The digital inking system of claim 1, wherein a region of the electronic display device within the housing surrounding the plurality of light converting regions is not hermetically sealed such that the housing includes at least one pathway for oxygen to traverse into the housing to reach the plurality of light converting regions.

4. The digital inking system of claim 1, wherein each of the plurality of light converting regions comprises a quantum dot.

5. The digital inking system of claim 1, further comprising a digital writing device, the digital writing device comprising a body that supports a UV light source and the optical sensor.

6. The digital inking system of claim 5, wherein the digital inking system is configured to track a position of the digital writing device to produce a digital representation of movement of the digital writing device.

7. The digital inking system of claim 1, wherein the optical sensor is equipped with a filter allowing only infrared portions of the light emitted by the plurality of light converting regions to reach the optical sensor.

8. The digital inking system of claim 1, wherein each of the plurality of light converting regions comprises:
a layer of a first III-V compound; and
a layer of a second III-V compound, wherein the first III-V compound is different from the second III-V compound.

9. The digital inking system of claim 8, wherein the first III-V compound is GaN and the second III-V compound is AlN.

10. The digital inking system of claim 1, wherein the plurality of light converting regions are coupled to an inward facing major surface supported by the housing.

11. The digital inking system of claim 10, wherein the plurality of light converting regions are directly deposited on to the inward facing major surface such that a portion of each of the light converting regions contacts the inward facing major surface.

12. The digital inking system of claim 1, further comprising a cover layer and a support layer located within the housing below the cover layer, wherein the cover layer is supported by the housing and comprises the outward facing major surface, and wherein the plurality of light converting regions are directly coupled to a first major surface of the support layer such that a portion of each of the light converting regions contacts the first major surface of the support layer.

13. The digital inking system of claim 12, wherein the cover layer is formed from a first glass material and the support layer is formed from a second glass material different from the first glass material.

14. The digital inking system of claim 12, further comprising a display stack, wherein the support layer is positioned on top of the display stack such that the plurality of light converting regions are located between the display stack and the cover layer.

15. A method of operating a digital inking system, the method comprising:
emitting UV light from a UV light source supported by a digital writing device;
absorbing the UV light by specific light converting regions of a plurality of light converting regions of an electronic display device, wherein the plurality of light converting regions are arranged in a pattern relative to an outward facing major surface of the electronic display device, and wherein the pattern encodes information indicating a spatial location of each light converting region relative to the outward facing major surface;
emitting light, in response to the absorbed light, from the specific light converting regions of the plurality of light converting regions, wherein a substantial portion of the light emitted from the specific light converting regions is in the near IR or IR wavelength ranges; and
detecting, by an optical sensor supported by the digital writing device, the light emitted from the specific light converting regions.

16. The method of claim 15, wherein the digital writing device comprises a communication system, and wherein the method further comprises:
communicating, from the communication system to a processing system, information indicating the spatial location of the specific light converting regions; and
producing a digital representation of movement of the digital writing device from the spatial location of the specific light converting regions.

17. The method of claim 16, further comprising causing the electronic display device to display a digital image that is representative of the movement of the digital writing device.

18. The method of claim 15, wherein the electronic display device comprises a cover layer comprising the outward facing major surface, and wherein emitting UV light from the UV light source occurs when a tip of the digital writing device engages with the cover layer.

19. The method of claim 15, wherein each of the plurality of light converting regions comprises:
a layer of a first III-V compound; and
a layer of a second III-V compound, wherein the first III-V compound is different from the second III-V compound.

20. The method of claim 15, wherein each of the plurality of light converting regions comprises a quantum dot.
